(19) United States
(12) Patent Application Publication
(10) Pub. No.: US 2025/0175215 A1
(43) Pub. Date: May 29, 2025

(54) RECONFIGURABLE MILLIMETER-WAVE INTELLIGENT SURFACE USING PIEZOELECTRIC ACTUATORS

(71) Applicant: Dell Products L.P., Round Rock, TX (US)

(72) Inventors: Navjot Kaur Khaira, Kanata (CA); Tejinder Singh, Kanata (CA); Morris Repeta, Ottawa (CA)

(21) Appl. No.: 18/523,434

(22) Filed: Nov. 29, 2023

(51) Int. Cl. H04B 7/04; H10N 30/20; H10N 39/00

(52) U.S. Cl. CPC H04B 7/04013; H10N 30/206; H10N 39/00

(57) ABSTRACT

A reconfigurable intelligent surface is disclosed. The reconfigurable intelligent surface includes a moveable metallic ground plane and piezoelectric actuators that are connected to the moveable metallic ground plane. Applying a voltage to the piezoelectric actuators causes the piezoelectric actuators to move the moveable metallic ground plane, which results in a change in a thickness of an air cavity formed in the reconfigurable intelligent surface. This allows a signal to be reflected to be steered in a continuous manner by changing the thickness of the air cavity. The reconfigurable intelligent surface may be a panel that includes multiple cells arranged to reflect and steer an incident signal.

### FIELD OF THE INVENTION

Embodiments of the present invention generally relate to reconfigurable intelligent surfaces. More particularly, at least some embodiments of the invention relate to systems, hardware, software, computer-readable media, and methods for reconfigurable intelligent surfaces that include a tunable air gap for beam steering.

### BACKGROUND

Cellular wireless communication is primarily based on 5G technology. 5G wireless networks was intended to deliver Gigabit data speeds, low latencies, and an improved user experience. These goals have been generally achieved. The telecom industry, however, is working to deliver sixth generation (6G) wireless communications.

Current radio frequency (RF) bands (5G bands) are largely saturated. As a result, the next logical step is to tap into the less saturated higher frequency bands. This approach, however, presents new challenges. For example, higher frequencies correspond to smaller wavelengths. Signals at these frequencies can be adversely impacted by physical barriers (e.g., buildings, vehicles, trees). The physical barriers can absorb, reflect, or scatter these higher frequency signals. Thus, these higher frequency signals may experience loss in free space. Establishing countless transceiver points for line-of-sight communications seems impractical.

A potential solution that has recently emerged includes reconfigurable intelligent surfaces (RIS) or intelligent reflective surfaces (IRS). A reconfigurable intelligent surface is a sophisticated assembly of hundreds, sometimes even thousands, of individual metamaterial unit cells. Currently, most of these unit cells require components such as PIN diodes, varactors, and/or switches to operate effectively. However, the binary nature of each switch or diode (on/off) presents a limitation. The presence of two states inevitably restricts the possible phase outcomes of the signal.

In addition to the restrictions on the phase outcome, current reconfigurable intelligent surface technologies present other issues. For example, conventional technologies require the signal to be received, actively processed (e.g., amplify and forward (AF), decode and forward (DF)), and retransmitted. Processing the signal can negatively impact the signal quality. AF, for example, can lead to noise amplification and DF can introduce decoding errors. Additionally, AF and DF cannot be readily incorporated into existing infrastructure like building walls or billboards due to at least the processing and amplification (e.g., power) requirements.

Conventional RIS technologies include the use of PIN diodes/varactors. PIN diodes and varactors have been extensively used in radio frequency (RF) applications due to their switching and tuning capabilities. However, several characteristics limit their effectiveness with respect to millimeter-wave (mmWave) applications. As the operating frequency increases, the parasitic capacitance and inductance associated with the device layout become more pronounced. These parasitic elements can resonate with the junction capacitance of the diodes, causing a significant degradation in performance and limiting the overall operational bandwidth. Both PIN diodes and varactors have a maximum operating frequency, and their performance drops drastically at frequencies above their maximum operating frequency.

PIN diodes are often used to implement reconfigurable properties in reconfigurable intelligent surfaces because they can act as variable resistors or switches when controlled by a bias current. This allows a level of control over the electromagnetic response of each element. However, the reconfigurability achieved using PIN diodes has certain limitations.

For example, a common application of PIN diodes in reconfigurable intelligent surfaces involves their use as binary switches. In this role, PIN diodes can only provide two phase states (e.g., 0° and 180°). This binary control limits the precision of phase tuning and, consequently, the resolution of beam steering and wavefront shaping.

PIN diodes also require a bias current to change their state and actively consume power. This power consumption can become an issue, particularly in large-scale reconfigurable intelligent surface systems that include large numbers of PIN diodes or varactors.

Next, in the active state, PIN diodes operate in a nonlinear region. This can lead to distortions in the signal passing through them, especially at high power levels. This distortion can degrade the quality of the signal and reduce the effectiveness of the reconfigurable intelligent surface.

In addition, the speed at which a PIN diode can switch states (and thus the speed at which the RIS can be reconfigured) is determined by the carrier lifetime in the diode. While this is typically fast enough for many applications, there are many high-speed scenarios in which the switching speed is inadequate.

Implementing PIN diodes on a reconfigurable intelligent surface introduces additional design complexity and cost, as each diode requires its own biasing network. In addition, the fact that each diode needs to be individually controlled to achieve the desired global effect can lead to challenges in terms of control complexity and efficiency.

With the transition to higher frequencies such as may be used in 6G applications, the physical dimensions of these components and the circuit become an important factor. Designing compact, integrated circuits with PIN diodes or varactors that can operate at millimeter-wave frequencies can be challenging.

### BRIEF DESCRIPTION OF THE DRAWINGS

In order to describe the manner in which at least some of the advantages and features of the invention may be obtained, a more particular description of embodiments of the invention will be rendered by reference to specific embodiments thereof which are illustrated in the appended drawings. Understanding that these drawings depict only typical embodiments of the invention and are not therefore to be considered to be limiting of its scope, embodiments of the invention will be described and explained with additional specificity and detail through the use of the accompanying drawings.

FIGS. 1A-1C disclose aspects of a unit cell;

FIG. 2 discloses aspects of a simulated reflection magnitude of a unit cell at 40 GHZ for different air cavity thicknesses;

FIG. 3 discloses aspects of a simulated reflection magnitude of a unit cell at 28 GHz for different air cavity thicknesses;

FIGS. 4A-4C discloses aspects of a reconfigurable intelligent surface panel;

FIGS. 5A-5C discloses aspects of beam steering using a reconfigurable intelligent surface panel;

FIG. 6 discloses aspects of deploying panels or reconfigurable intelligent surfaces in an environment;

FIG. 7 discloses aspects of deploying panels or reconfigurable intelligent surfaces in another environment;

FIG. 8 discloses aspects of a method for deploying and operating panels or reconfigurable intelligent surfaces; and

FIG. 9 discloses aspects of a computing device, system, or entity.

### DETAILED DESCRIPTION OF SOME EXAMPLE EMBODIMENTS

Embodiments of the present invention generally relate to reconfigurable intelligent surfaces. More particularly, at least some embodiments of the invention relate to systems, hardware, software, computer-readable media, and methods for reconfigurable intelligent surfaces that include a tunable air gap for beam steering.

Embodiments of the invention further relate to a reconfigurable intelligent surface that is capable of reflecting wireless signals. Reconfigurable intelligent surfaces in accordance with embodiments of the invention can operate as a relay node that transmits signals to the other side of the reconfigurable intelligent surface or a reflection node. This provides greater flexibility in deploying reconfigurable intelligent surfaces and in expanding their potential applications.

A reconfigurable intelligent surface is an engineered two-dimensional surface outfitted with passive elements or unit cells and may include metamaterials. A panel that includes a grid or arrangement of unit cells is an example of a reconfigurable intelligent surface. A reconfigurable intelligent surface functions by manipulating a phase response of each unit cell. This adjusts the propagation of incident wireless signals and enables smart radio environments (SREs).

Embodiments of the invention, such as the examples disclosed herein, may be beneficial in a variety of respects. For example, and as will be apparent from the present disclosure, one or more embodiments of the invention may provide one or more advantageous and unexpected effects, in any combination, some examples of which are set forth below. It should be noted that such effects are neither intended, nor should be construed, to limit the scope of the claimed invention in any way. It should further be noted that nothing herein should be construed as constituting an essential or indispensable element of any invention or embodiment. Rather, various aspects of the disclosed embodiments may be combined in a variety of ways so as to define yet further embodiments. For example, any element(s) of any embodiment may be combined with any element(s) of any other embodiment, to define still further embodiments. Such further embodiments are considered as being within the scope of this disclosure. As well, none of the embodiments embraced within the scope of this disclosure should be construed as resolving, or being limited to the resolution of, any particular problem(s). Nor should any such embodiments be construed to implement, or be limited to implementation of, any particular technical effect(s) or solution(s). Finally, it is not required that any embodiment implement any of the advantageous and unexpected effects disclosed herein.

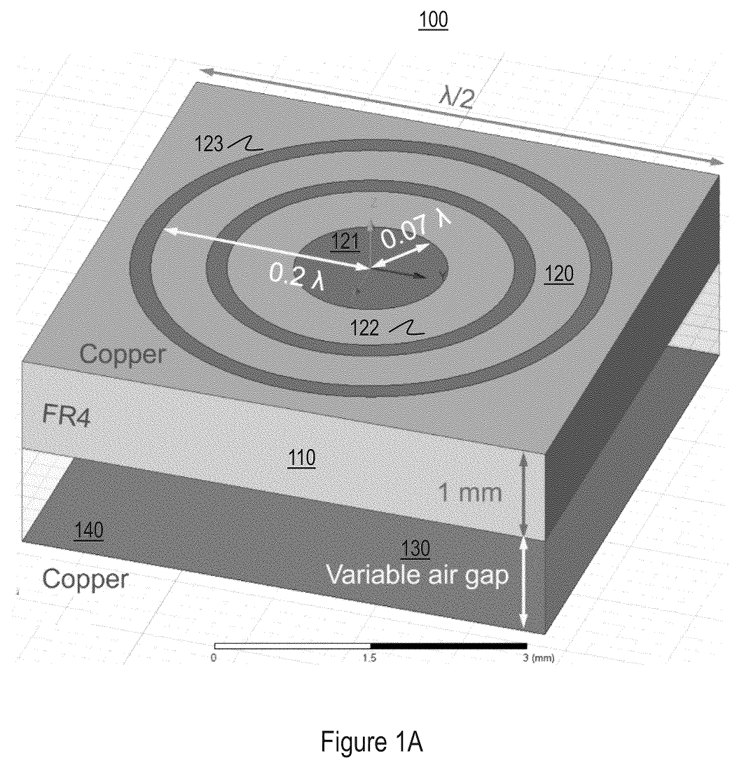

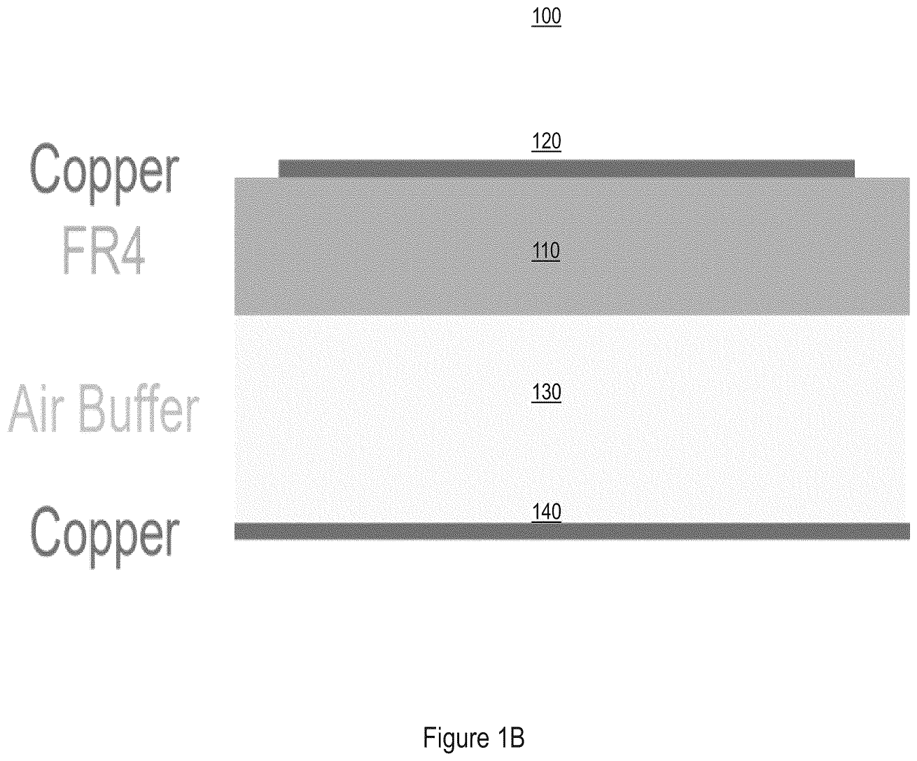

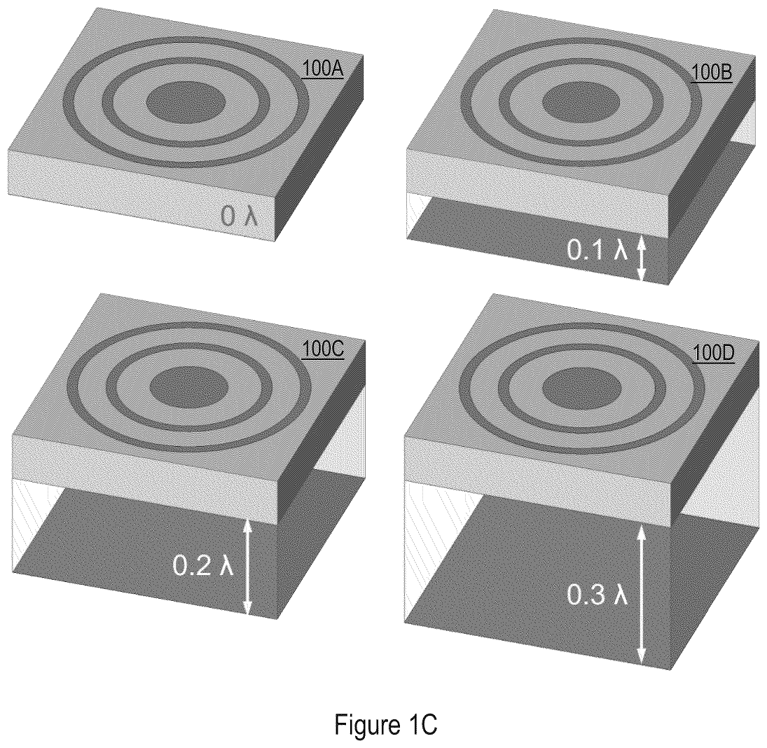

FIGS. 1A and 1B illustrate a unit cell 100 that can be implemented in a reconfigurable intelligent surface. The unit cell 100 in FIGS. 1A and 1B illustrates various layers of a unit cell that may be included in a reconfigurable intelligent surface as will be explained in more detail to follow. As shown in FIG. 1A, the unit cell 100 includes a dielectric substrate 110. In one embodiment, the dielectric substrate 110 may be made of FR4, a type of printed circuit board material that may include epoxy resin and glass composite. However, in other embodiments the dielectric substrate 110 may be made of silicon, glass, sapphire, quartz, Rogers RF substrates, or any other suitable dielectric material.

In the embodiment of FIGS. 1A and 1B, the dielectric substrate 110 has a thickness of 1 mm. However, the dielectric substrate 110 may also be implemented in any suitable thickness as circumstances warrant. In addition, in the embodiment the dielectric substrate 110 is has a square shape with sides having a length of λ/2, where λ is the wavelength of light is a vacuum. However, in other embodiments the dielectric substrate 110 may have a different thickness or shape as design and use circumstances warrant. Accordingly, the embodiments disclosed herein are not limited to any particular type of material, thickness, or shape of the dielectric substrate 110.

The dielectric substrate 110 includes a metallic element 120 that is printed on a top surface of the dielectric substrate 110. In one embodiment, the metallic element 120 is made of copper. However, any other suitable conducting metal may also be used to implement the metallic element 120. In the embodiment of FIGS. 1A and 1B, the metallic element 120 is implemented as three concentric circular loops 121, 122, and 123. The inner concentric circular loop 121 has a radius of 0.007 λ, the outer circular loop 123 has a radius of 0.2 λ, and the middle concentric circular loop 122 has a radius in between the inner and outer circular loops. However, in other embodiments the metallic element 120 may be other shapes besides concentric circular loops such as concentric squares or rings. In general, the metallic element 120 is configured to have a shape such that the metallic element 120 is resonant with an incident signal or electromagnetic wave incident on the unit cell 100. Accordingly, the embodiments disclosed herein are not limited to any particular shape for the metallic element 120.

The unit cell 100 also includes a variable or adjustable air cavity 130 and a movable metallic ground plane 140. As will be explained in more detail to follow, the air cavity 130 can be adjusted by raising or lowering the movable metallic ground plane 140 with respect to the dielectric substrate 110 to tune a reflected signal response of the unit cell 100. In one embodiment, the movable metallic ground plane 140 is made of copper. However, in other embodiments the movable metallic ground plane 140 may be made of any suitable conducting metal.

FIG. 1B illustrates a side view of the unit cell 100. As illustrated, the unit cell 100 includes the dielectric substrate 110, which in the embodiment is made of FR4, the printed metallic element 120, which in the embodiment is made of copper, the variable or adjustable air cavity 130, and the movable metallic ground plane 140, which in the embodiment is made of copper.

As previously mentioned previously, the air cavity 130 of each unit cell 100 can be adjusted by raising or lowering the movable metallic ground plane 140 with respect to the dielectric substrate 110 to tune a reflected signal response of the unit cell 100. FIG. 1C illustrates an embodiment of a unit cell 100A where there is no air cavity 130. That is, in the unit cell 100A, the movable metallic ground plane 140 contacts the dielectric substrate 110. An embodiment of a unit cell 100B shows an air cavity 130 at a first air cavity thickness 0.1 λ produced as the movable metallic ground plane 140 is lowered from its location in unit cell 100A. An embodiment of a unit cell 100C shows an air cavity 130 at a second air cavity thickness 0.2 λ produced as the movable metallic ground plane 140 is lowered from its location in unit cell 100B. An embodiment of a unit cell 100D shows an air cavity 130 at a third air cavity thickness 0.3 λ produced as the movable metallic ground plane 140 is lowered from its location in unit cell 100B.

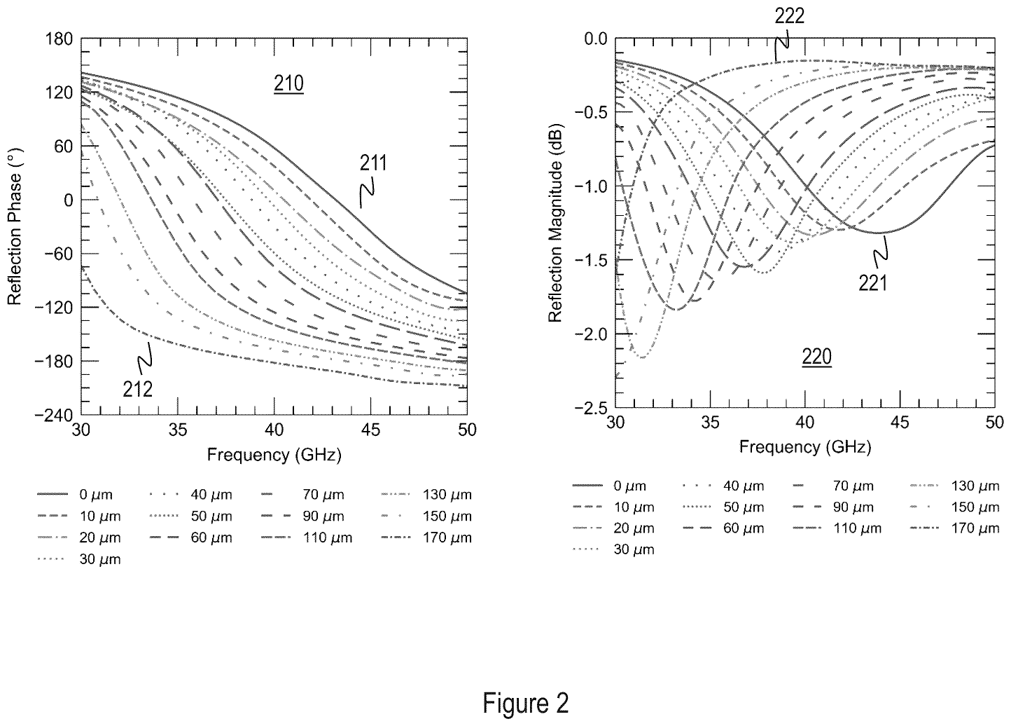

FIG. 2 illustrates aspects of a simulated reflection phase of a unit cell 100 at 40 GHz for different air cavity 130 thicknesses in a graph 210. The Y-axis of the graph 210 shows the reflection phases in degrees and the X-axis shows the frequency from 30 GHz to 50 GHz. In the simulation, the air cavity 130 thickness is changed from 0 μm to 170 μm in increments of 10 μm. The reflection phase at an air cavity thickness of 0 μm is shown by curve 211 and the reflection phase of an air cavity thickness of 170 μm is shown by curve 212. The remaining curves of the graph 210 show the reflection phase of air cavity thicknesses between 0 μm and 170 μm in increments of 10 μm. It can be observed from graph 210 that there is a significant reflection phase shift of 240 degrees between the air cavity thicknesses of 0 μm and 170 μm.

FIG. 2 also illustrates aspects of a simulated reflection magnitude of a unit cell 100 at 40 GHz for different air cavity 130 thicknesses in a graph 220. The Y-axis of the graph 220 shows the reflection magnitude in dB and the X-axis shows the frequency from 30 GHz to 50 GHz. In the simulation, the air cavity 130 thickness is changed from 0 μm to 170 μm in increments of 10 μm. The reflection magnitude at an air cavity thickness of 0 μm is shown by curve 221 and the reflection magnitude of an air cavity thickness of 170 μm is shown by curve 222. The remaining curves of the graph 210 show the reflection magnitudes of air cavity thicknesses between 0 μm and 170 μm in increments of 10 μm. It can be observed from graph 220 that there is a significant change in the reflection magnitude between the air cavity thicknesses of 0 μm and 170 μm. Thus, graphs 210 and 220 show that by adjusting the air cavity 130 thickness, the reflected signal response of a unit cell 100 can be changed.

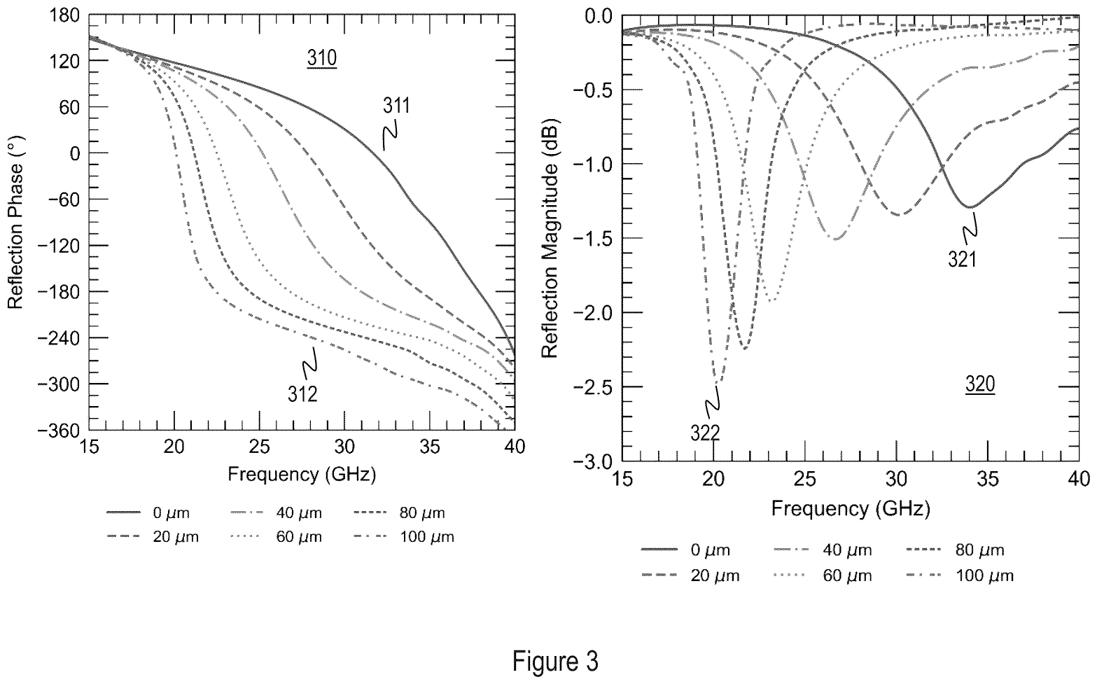

FIG. 3 illustrates aspects of a simulated reflection phase of a unit cell 100 at 28 GHZ for different air cavity 130 thicknesses in a graph 310. The Y-axis of the graph 310 shows the reflection phases in degrees and the X-axis shows the frequency from 15 GHz to 40 GHz. In the simulation, the air cavity 130 thickness is changed from 0 μm to 100 μm in increments of 20 μm. The reflection phase at an air cavity thickness of 0 μm is shown by curve 311 and the reflection phase of an air cavity thickness of 100 μm is shown by curve 312. The remaining curves of the graph 310 show the reflection phase of air cavity thicknesses between 0 μm and 100 μm in increments of 20 μm. It can be observed from graph 310 that there is a significant reflection phase shift of 300 degrees between the air cavity thicknesses of 0 μm and 100 μm.

FIG. 3 also illustrates aspects of a simulated reflection magnitude of a unit cell 100 at 28 GHz for different air cavity 130 thicknesses in a graph 320. The Y-axis of the graph 320 shows the reflection magnitude in dB and the X-axis shows the frequency from 15 GHz to 40 GHz. In the simulation, the air cavity 130 thickness is changed from 0 μm to 100 μm in increments of 20 μm. The reflection magnitude at an air cavity thickness of 0 μm is shown by curve 321 and the reflection magnitude of an air cavity thickness of 100 μm is shown by curve 322. The remaining curves of the graph 320 show the reflection magnitudes of air cavity thicknesses between 0 μm and 100 μm in increments of 20 μm. It can be observed from graph 320 that there is a significant change in the reflection magnitude between the air cavity thicknesses of 0 μm and 100 μm. Thus, graphs 310 and 320 show that by adjusting the air cavity 130 thickness, the reflected signal response of a unit cell 100 can be changed.

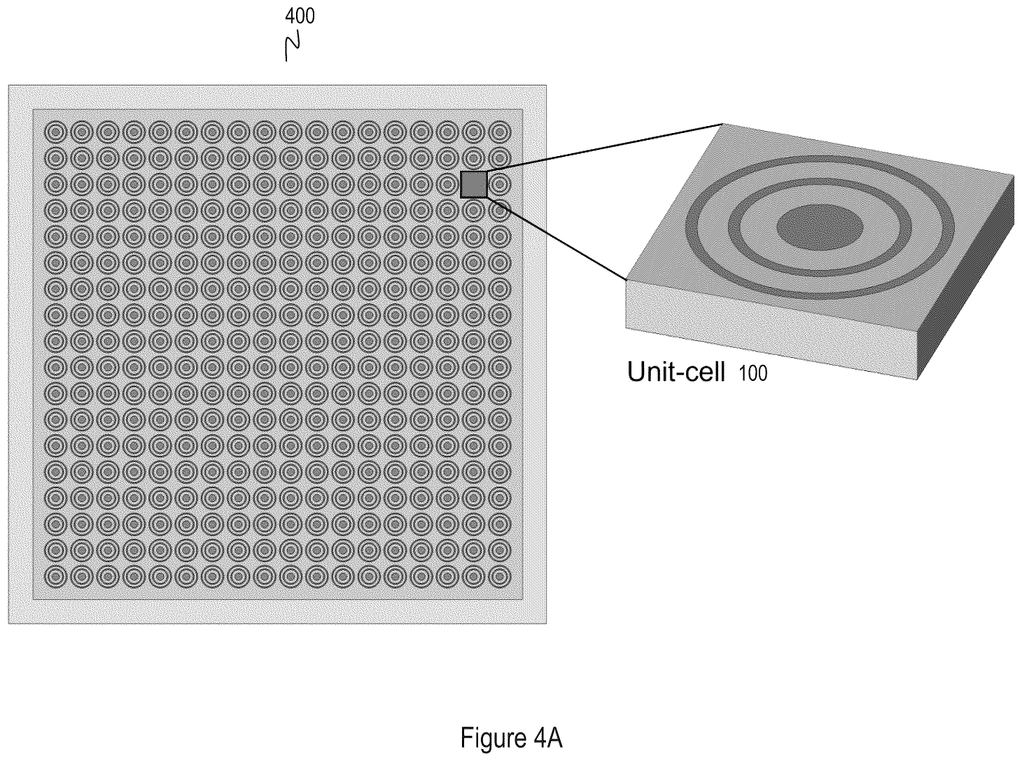

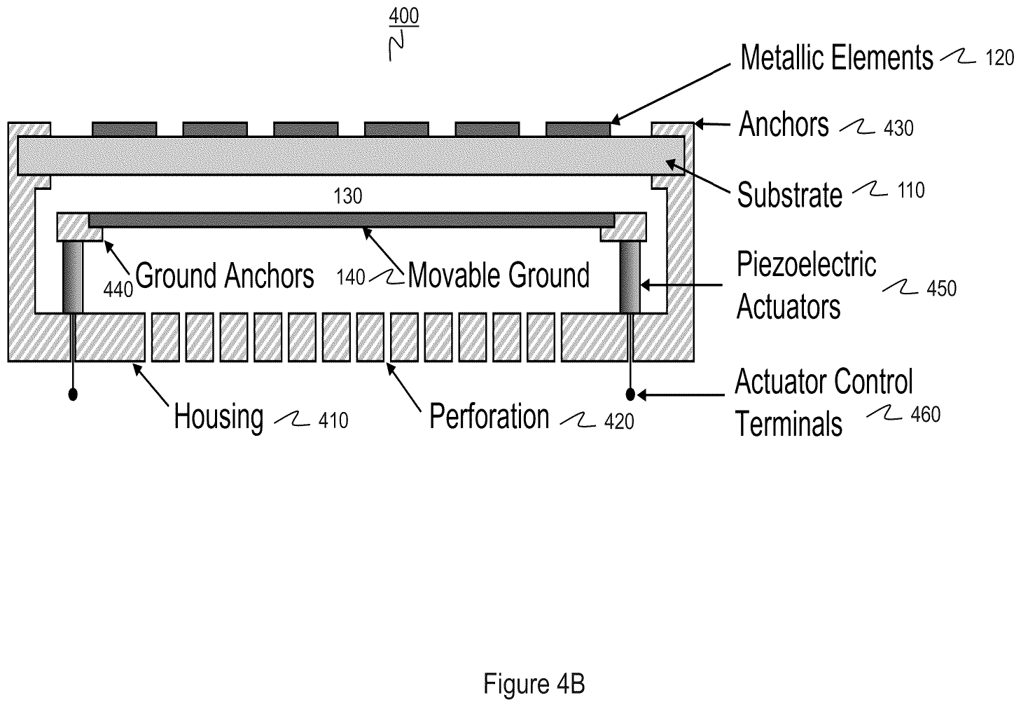

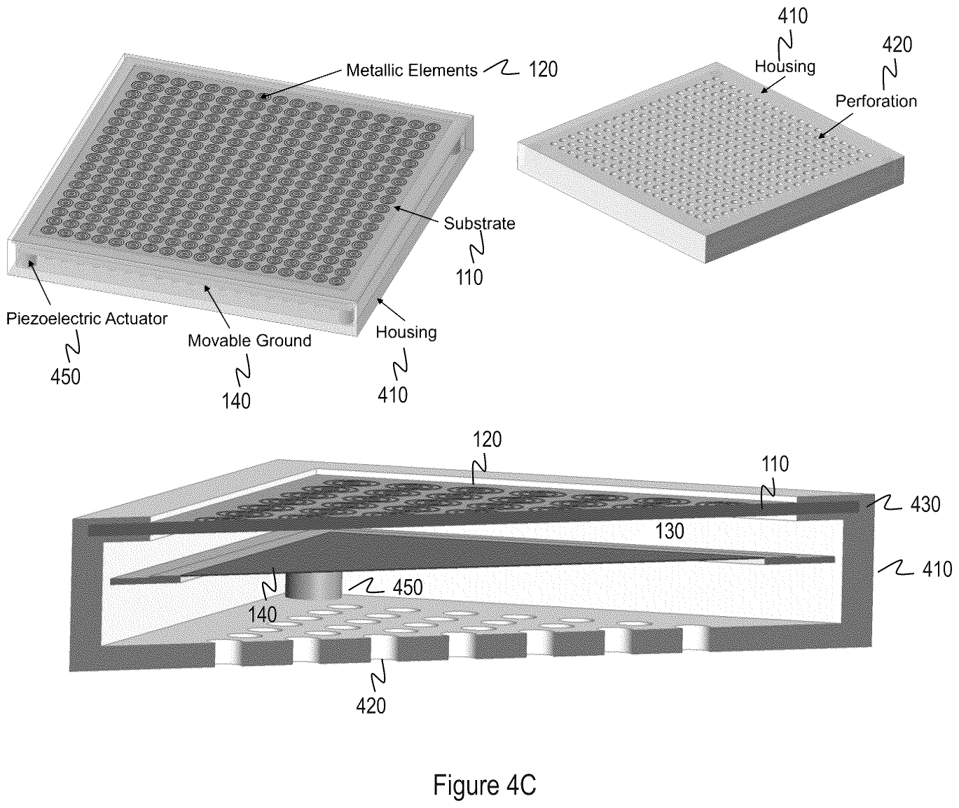

As mentioned previously, the unit cells 100 can be implemented as part of a reconfigurable intelligent surface (RIS) panel. FIGS. 4A-4D illustrate an embodiment of a RIS panel 400 where the unit cells 100 are arranged in a two-dimensional array that forms the structure of the RIS panel 400. In the embodiment of FIG. 4A, the RIS panel 400 is implemented as a panel having an 18×18 array of unit cells. It will be noted, however, that the RIS panel 400 may be implemented as an array having any number of unit cells 100 as design and operational circumstance dictate. In the RIS panel 400, a reflected signal from each unit cell 100 undergoes constructive interference resulting in a directional beam as will be explained in more detail to follow.

FIGS. 4B and 4C illustrate an embodiment of the structure of the RIS panel 400. As illustrated in FIG. 4B, which shows a cross section of the RIS panel 400, the RIS panel 400 includes the various metallic elements 120 for each of the unit cells 100. The metallic elements 120 are patterned on the dielectric substrate 110 as previously described. The RIS panel 400 also includes the movable metallic ground plane 140.

The RIS panel 400 also includes a housing 410 that houses the various elements of the RIS panel 400. In one embodiment, the housing 410 has a square shape and is made of a transparent RF plastic, although other suitable shapes and materials may also be used as design and operational circumstances warrant. In some embodiments the housing 410 includes perforations 420, which function as air escape channels that allow air to escape from the interior of the housing 410 when the movable metallic ground plane 140 is moved to change the size of the air cavity 130. This advantageously allows for the size of the air cavity to be changed without the interior air acting to impede the movement of the movable metallic ground plane 140 since the interior air is able to escape. Although the perforations 420 are shown as being on the bottom surface of the housing 410, this need not be the case. In some embodiments perforations may be made in the dielectric substrate 110 to allow the interior air to escape. In still other embodiments, the perforations 420 may be made in one or more of the side walls of the housing. In further embodiments, the perforations 420 may be made in any combination of the sides of the housing.

The housing 410 includes anchors 430 that are shaped so that the dielectric substrate 110 is able to fit into the housing 410. As shown in FIG. 4C, in the embodiment where the housing 410 is a square shape, the anchors are implemented as a groove that runs along a top surface of the housing and that allows the dielectric substrate 110 to be inserted into the groove. In other embodiments, the anchors 430 may be implemented using other suitable means for connecting the dielectric substrate 110 to the housing 410.

The housing 410 also includes ground anchors 440. The ground anchors 440 are shaped so that the movable metallic ground plane 140 is able to be fit into the ground anchors. In this way, the ground anchors 440 support the movable metallic ground plane 140 and allow it to be moved up and down as needed. The ground anchors 440 may be made from the same material as the housing 410, such as transparent RF plastic, but may also be made from a different material as circumstances warrant.

To allow the movable metallic ground plane 140 to move up and down so as to change the size of the air cavity 130, the RIS panel 400 includes piezoelectric actuators 450 that are attached to both the bottom surface of the housing 410 and to the ground anchors 440. The piezoelectric actuators 450, when provided a DC voltage via control terminals 460 that extend from the bottom surface of the housing 410, are able to move up or down, which in turn moves the movable metallic ground plane 140 up or down as needed to increase or decrease the air cavity thickness.

Although any reasonable piezoelectric actuator may be used, in one embodiment a stacked ceramic disk piezoelectric actuator made of lead (Pb) zirconate (Zr) titanate (Ti), also known as PZT, is used. Each disk in the stack exhibits the characteristic of vertical expansion when an electric potential is applied, a property attributed to the piezoelectric effect. The disks in the stack are divided by slim metallic electrodes which apply the voltage. As a result, a substantial cumulative expansion is possible, equal to the sum of the expansions of each individual disk.

As shown in FIG. 4C, in the embodiment where the housing 410 is a square shape there are four piezoelectric actuators 450 included in the housing 410, one at each corner. In one embodiment, as show in FIG. 4B, when the housing 410 is a straight plane, the air cavity 130 under all the unit cells can be changed equally when all of the piezoelectric actuators 450 are controlled to provide equal displacement of the movable metallic ground plane 140.

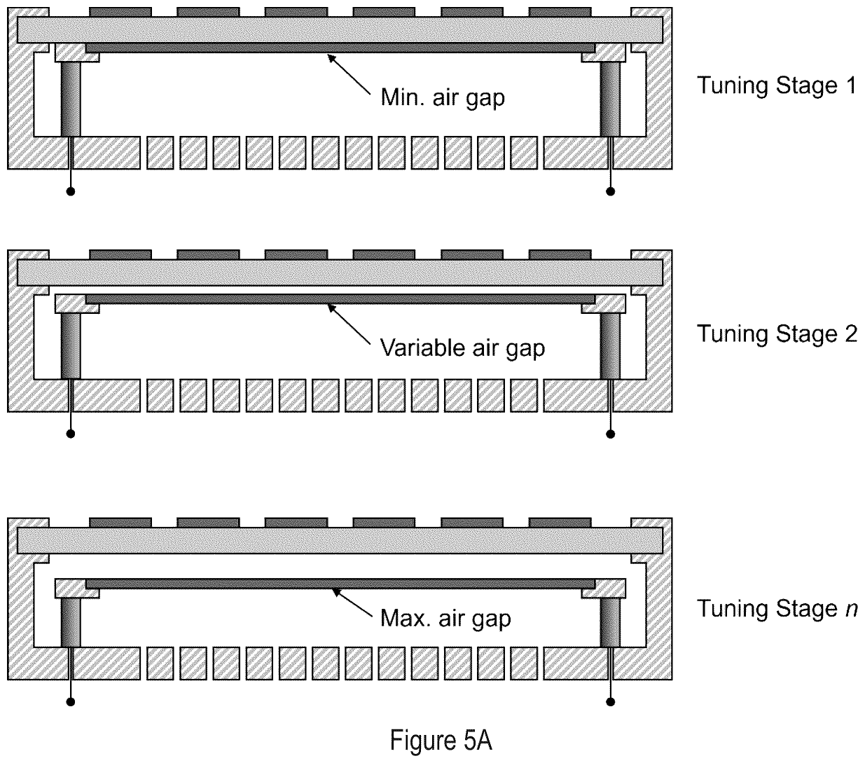

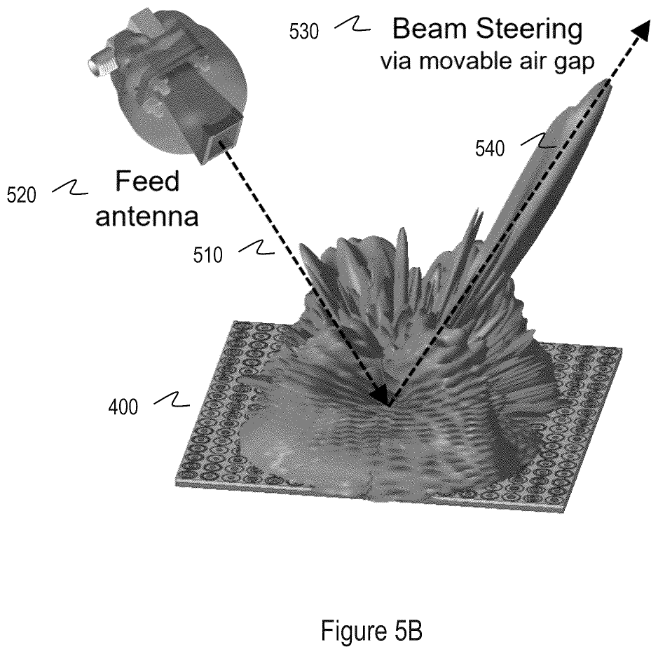

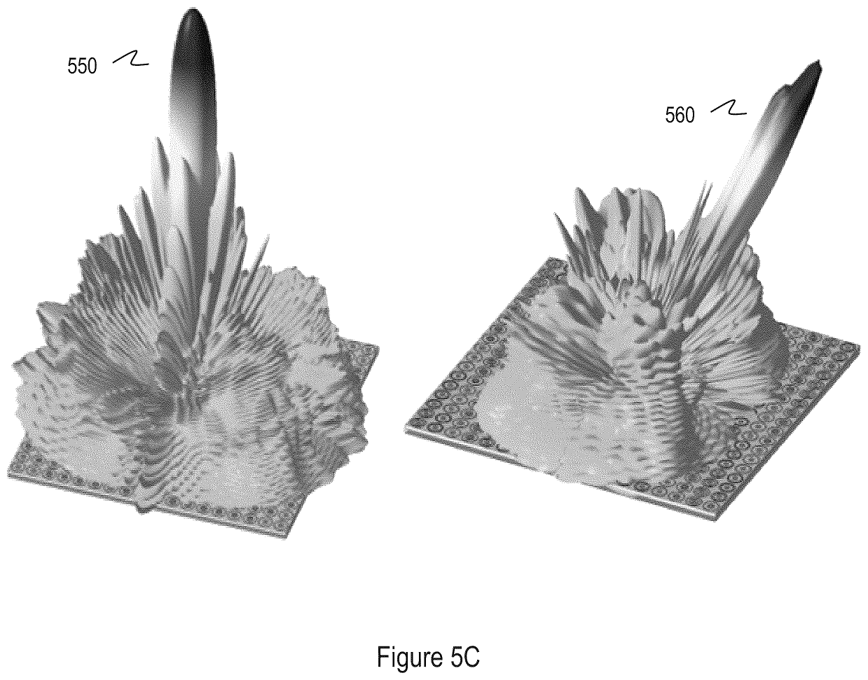

Advantageously, implementing the piezoelectric actuators 450 in the RIS panel 400 to move the movable metallic ground plane 140 provides for mechanical like beam steering without making the overall system too bulky. FIGS. 5A-5C illustrate aspects of beam steering using the RIS panel 400.

FIG. 5A shows a cross section view of the RIS panel 400 during a tuning phase. During a tuning stage 1, the piezoelectric actuators 450 cause the movable metallic ground plane 140 to contact the dielectric substrate 110 and thus a minimum air cavity 130 is generated. During a tuning stage 2, the piezoelectric actuators 450 have lowered the movable metallic ground plane 140 a given amount, thus generating the air cavity 130 having a first thickness. The tuning stages can be repeated until a tuning stage n. In the tuning state n, the piezoelectric actuators 450 have lowered the movable metallic ground plane 140 to its lowest point, thus generating the air cavity 130 having a maximum thickness. Thus, by moving the movable metallic ground plane 140 up and down, the size of the air cavity 130 is changed. When an electromagnetic beam is incident on the RIS panel 400 from a nearby access point of base station, beam steering is achieved by changing the size of the air cavity 130.

Simulations were run where an electromagnetic beam 510 is generated by a horn feed antenna 520 that is placed at a certain angle and distance away from the center of the RIS panel 400 panel. By moving the movable metallic ground plane 140 to change the size of the air cavity 130, beam steering 530 of a reflected electromagnetic beam 540 is achieved.

FIG. 5C shows examples of the simulated response form the RIS panel 400. As shown at 550, in a first simulation the reflected beam 540 is in the direction θ=0° and Φ=0°. In one embodiment, the first simulation corresponds to a center frequency and is achieved by the tuning stage 1, that is having no or minimal air cavity 130. As shown at 560, in a second simulation the reflected beam 540 is in the direction θ=30° and Φ=0°. In one embodiment, the second simulation corresponds to the tuning stage 2, where the movable metallic ground plane 140 has been moved to increase the size or thickness of the air cavity 130. Such an increase in the size or thickness of the air cavity results in a 30 degree change in the reflection phase, thus steering the reflected electromagnetic beam 540. Of course, changing the size or thickness of the air cavity 130 by further movement of the movable metallic ground plane 140 will result in further beam steering of the reflected electromagnetic beam 540.

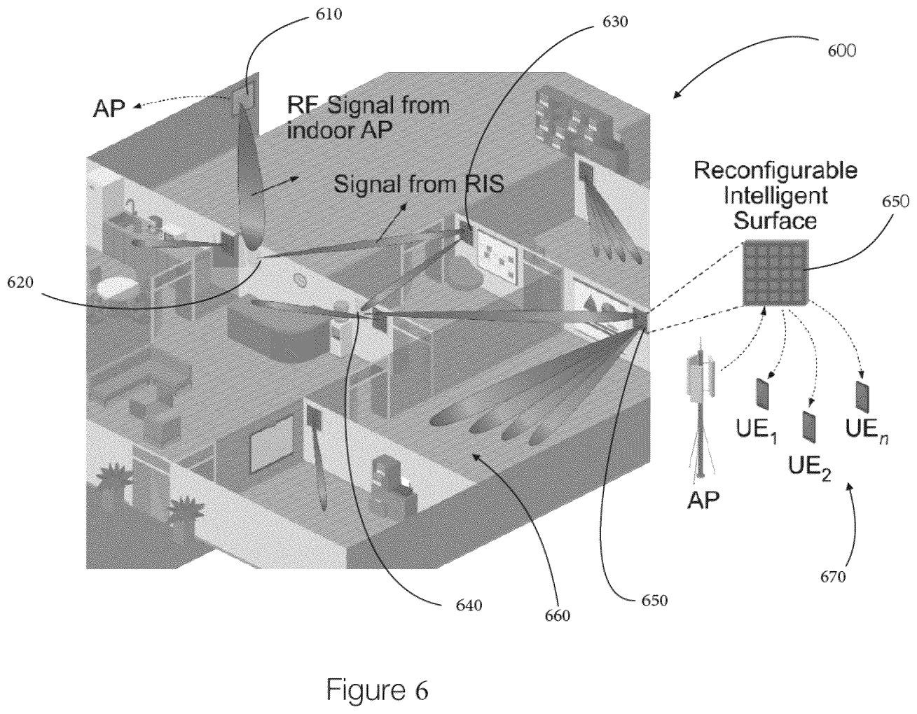

FIG. 6 discloses aspects of steering signals in an environment. FIG. 6 illustrates an indoor environment 600, such as a working environment (e.g., a building) of an entity. The indoor environment 600 may be cluttered with many obstructions, including walls, furniture, and appliances, which can block or degrade wireless signals, such as by way of example only mmWave signals. Reconfigurable intelligent surfaces (e.g., panels) can be strategically installed on walls, ceilings, or other surfaces, and can be used to reflect and steer these signals towards selected regions or locations. As illustrated in FIG. 6, reconfigurable intelligent surfaces may receive a signal from the indoor access point and redirect the signal to areas where the signal, which is transmitted by the gateway or router, is weak or non-existent. Embodiments of the invention may be used in multi-story buildings to direct signals to upper or lower floors.

Reconfigurable intelligent surfaces not only improve the coverage but can also improve the security of wireless communications. By selectively directing signals, the possibility of eavesdropping is reduced. Reconfigurable intelligent surface can add an additional layer of physical security by enabling secure transmission zones where only intended receivers can intercept the signals. The passive beamforming from reconfigurable intelligent surface improves energy efficiency by reducing wasteful signal dispersion and directing the signal only where required. Embodiments of the invention can be extended to smart homes where reconfigurable intelligent surfaces can intelligently steer signals towards connected devices like smart speakers, smart TVs, IoT sensors, etc., even when these devices are located in hard-to-reach areas.

More specifically, a wireless network may be established and include an access point 610 for the environment 600. Embodiments of the invention use panels that include multiple unit cells to steer or direct the signals. By way of example, panels 620, 630, 640, and 650 may be placed at various locations in the environment 600 (other panels are also illustrated). To provide wireless network coverage in the room 660, which may not receive a signal from the access point 610, the signal transmitted by the access point 610 is transmitted to the panel 620. The panel 620 includes unit cells 100 that are configured to direct or reflect the signal to the panel 630. The panel 630 is configured to direct or reflect the signal to the panel 640. The panel 640 is configured to direct or reflect the signal to the panel 650.

The panel 650 may be configured to direct or reflect the signal in multiple directions, using for example different unit cell configurations such that the signal can be directed to or received by multiple user equipment 670 (e.g., UE₁, . . . , UEₙ), to provide wireless coverage to user equipment or other devices in the room 660 or other locations. A wireless path back to the access point 610 may be similarly configured.

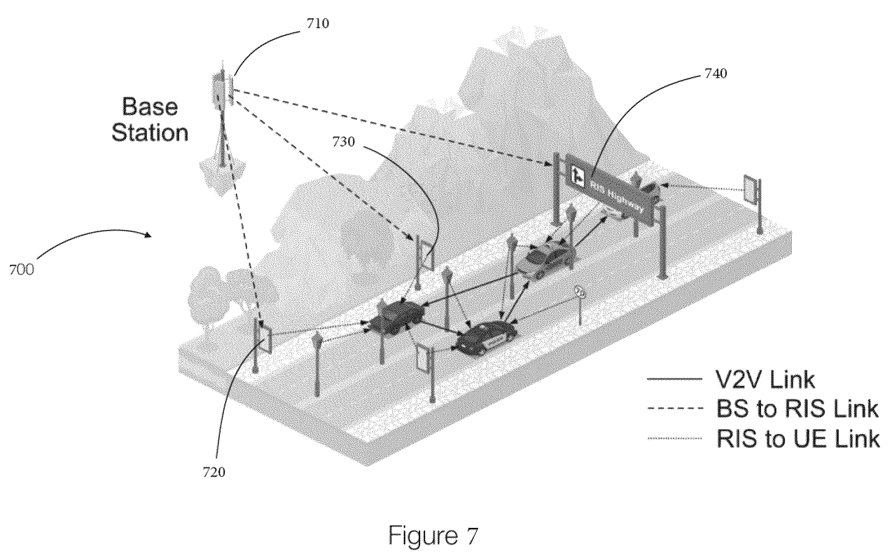

FIG. 7 discloses aspects of an environment in which reconfigurable intelligent surfaces may be deployed. FIG. 7 illustrates an outdoor environment 700 such as a highway or road. In this example, a base station 710 may broadcast a signal that can be redirected by panels placed in the environment 700. In this example, panels 720, 730, and 740 may be placed on overhead signs, lamp posts, road signs, and the like. This allows the signals to be redirected or reflected to provide coverage in the environment 700. Vehicle-to-vehicle (V2V) communication may be enabled using embodiments of the invention. V2V and autonomous vehicles benefit from high-speed, reliable, and low-latency wireless communication. Due to its high data rates, mmWave technology is considered as a potential enabler for these vehicular communication applications.

As illustrated in FIG. 7, panels can be deployed in specific locations to reflect mmWave signals towards the intended vehicle (or vehicles in a particular area), increasing the signal strength and improving the communication quality between vehicles. The coverage enhancement using reconfigurable intelligent surfaces is beneficial in vehicular networks as the vehicles may frequently go in and out of coverage areas. By extending the coverage of mmWave signals using reconfigurable intelligent surfaces, a smaller number of base stations and access points are needed. Reconfigurable intelligent surfaces can support Vehicle-to-Everything (V2X) communication, which involves communication between vehicles and any entity that may affect the vehicle, such as pedestrians, roadside infrastructure, or the network.

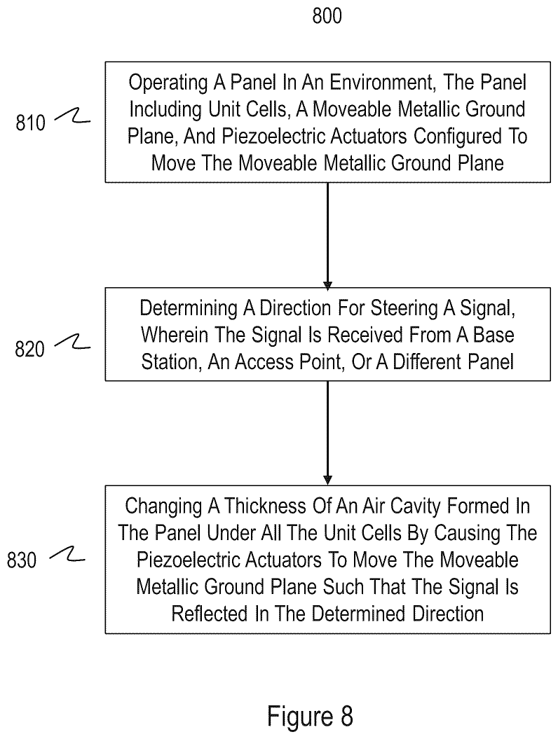

FIG. 8 discloses aspects of a method 800 for redirecting signals or electromagnetic waves in an environment. The method 800 includes operating a panel in an environment, the panel including unit cells, a moveable metallic ground plane, and piezoelectric actuators configured to move the moveable metallic ground plane (810). As previously described, the RIS panel 400 (or multiple RIS panels) are implemented in an environment such as those described in FIGS. 6 and 7. The RIS panel 400 includes the unit cells 100, the moveable metallic ground plane 140, and piezoelectric actuators 450.

The method 800 includes determining a direction for steering a signal, wherein the signal is received from a base station, an access point, or a different panel (820). As previously described in relation to FIGS. 5A-7, a signal or beam is received from a base station, access point, or different panel. A determination can then be made of a desired beam steering direction.

The method 800 includes changing a thickness of an air cavity formed in the panel under all the unit cells by causing the piezoelectric actuators to move the moveable metallic ground plane such that the signal is reflected in the determined direction (830). As previously described, the piezoelectric actuators 450 move the moveable metallic ground plane 140 so as to change the thickness of the air cavity 130. This change in the thickness of the air cavity 130 causes the RIS panel 400 to steer the signal or beam in the determined direction.

It is noted that embodiments of the invention, whether claimed or not, cannot be performed, practically or otherwise, in the mind of a human. Accordingly, nothing herein should be construed as teaching or suggesting that any aspect of any embodiment of the invention could or would be performed, practically or otherwise, in the mind of a human. Further, and unless explicitly indicated otherwise herein, the disclosed methods, processes, and operations, are contemplated as being implemented by computing systems that may comprise hardware and/or software. That is, such methods processes, and operations, are defined as being computer-implemented.

The following is a discussion of aspects of example operating environments for various embodiments of the invention. This discussion is not intended to limit the scope of the invention, or the applicability of the embodiments, in any way.

In general, embodiments of the invention may be implemented in connection with systems, software, and components, that individually and/or collectively implement, and/or cause the implementation of, signal processing operations, wireless coverage operations, signal steering or reflection operations, wireless coverage operations, or the like. More generally, the scope of the invention embraces any operating environment in which the disclosed concepts may be useful.

It is noted that any operation of any of the methods disclosed herein may be performed in response to, as a result of, and/or, based upon, the performance of any preceding operation. Correspondingly, performance of one or more operations, for example, may be a predicate or trigger to subsequent performance of one or more additional operations. Thus, for example, the various operations that may make up a method may be linked together or otherwise associated with each other by way of relations such as the examples just noted. Finally, and while it is not required, the individual operations that make up the various example methods disclosed herein are, in some embodiments, performed in the specific sequence recited in those examples. In other embodiments, the individual operations that make up a disclosed method may be performed in a sequence other than the specific sequence recited.

Following are some further example embodiments of the invention. These are presented only by way of example and are not intended to limit the scope of the invention in any way.

Embodiment 1. A panel comprising: a substrate; one or more metallic elements formed on a first surface of the substrate; a moveable metallic ground plane separated from a second surface of the substrate by an air cavity positioned between the moveable metallic ground plane and the second surface of the substrate; and a plurality of piezoelectric actuators attached to the moveable metallic ground plane and configured to increase or decrease a thickness of the air cavity by raising or lowering the moveable metallic ground plane, wherein increasing or decreasing the thickness of the air cavity causes the panel to steer an electromagnetic beam that is directed toward the panel.

Embodiment 2. The panel of embodiment 1, further comprising: a housing that comprises at least a bottom surface and two side surfaces; the two side surfaces including first anchor portions that are configured to anchor the substrate to the housing; the plurality of piezoelectric actuators and the moveable metallic ground plane being positioned between the substrate and the bottom surface of the housing; and the housing including second anchor portions that attach the moveable metallic ground plane to the plurality of piezoelectric actuators.

Embodiment 3. The panel of embodiment 1 and/or 2, wherein the housing comprises a plurality of perforations that are configured to allow air that is interior to the housing to escape through the perforations when the plurality of piezoelectric actuators move the moveable metallic ground plane.

Embodiment 4. The panel of embodiment 1, 2, and/or 3, wherein the perforations are positioned on one or more of the bottom surface of housing, one or both of the side surfaces of the housing, or the substrate.

Embodiment 5. The panel of embodiment 1, 2, 3, and/or 4, wherein the housing further includes control terminals that extend from the bottom surface of the housing and that are configured to provide a DC voltage to the piezoelectric actuators.

Embodiment 6. The panel of embodiment 1, 2, 3, 4, and/or 5, wherein the housing is made of a transparent RF plastic.

Embodiment 7. The panel of embodiment 1, 2, 3, 4, 5, and/or 6, wherein the plurality of piezoelectric actuators are positioned at corners of the housing.

Embodiment 8. The panel of embodiment 1, 2, 3, 4, 5, 6, and/or 7, wherein the one or more metallic elements are arranged in a grid-like array.

Embodiment 9. The panel of embodiment 1, 2, 3, 4, 5, 6, 7, and/or 8, wherein the substrate comprises a dielectric material.

Embodiment 10. The panel of embodiment 1, 2, 3, 4, 5, 6, 7, 8, and/or 9, wherein the one or more metallic elements formed on the first surface of the substrate have a shape that is resonant with an incident signal or electromagnetic wave incident on the panel.

Embodiment 11. A panel comprising: a housing; and a plurality of unit cells arranged in a grid pattern, the plurality of unit cells including: a substrate; a metallic layer that includes one or more metallic elements for each of the unit cells, the metallic layer formed on a first surface of the substrate; a moveable metallic ground plane separated from a second surface of the substrate by an air cavity positioned between the moveable metallic ground plane and the second surface of the substrate; and a plurality of piezoelectric actuators attached to the moveable metallic ground plane and configured to increase or decrease a thickness of the air cavity by raising or lowering the moveable metallic ground plane, wherein increasing or decreasing the thickness of the air cavity causes the panel to steer an electromagnetic beam that is directed toward the panel.

Embodiment 12. The panel of embodiment 11, wherein the housing comprises a plurality of perforations that are configured to allow air that is interior to the housing to escape through the perforations when the plurality of piezoelectric elements move the moveable metallic ground plane.

Embodiment 13. The panel of embodiment 11 and/or 12, wherein the plurality of piezoelectric actuators are positioned at corners of the housing.

Embodiment 14. The panel of embodiment 11, 12, and/or 13, wherein the substrate comprises a dielectric material.

Embodiment 15. The panel of embodiment 11, 12, 13, and/or 14, wherein the housing further includes control terminals that extend from the bottom surface of the housing and that are configured to provide a DC voltage to the plurality of piezoelectric actuators.

Embodiment 16. The panel of embodiment 11, 12, 13, 14, and/or 15, wherein the housing comprises at least a bottom surface and two side surfaces; the two side surfaces including first anchor portions that are configured to anchor the substrate to the housing; the plurality of piezoelectric actuators and the moveable metallic ground plane being positioned between the substrate and the bottom surface of the housing; and the housing including second anchor portions that attach the moveable metallic ground plane to the plurality of piezoelectric actuators.

Embodiment 17. The panel of embodiment 11, 12, 13, 14, 15 and/or 16, wherein the one or more metallic elements formed on the first surface of the substrate have a shape such that is resonant with an incident signal or electromagnetic wave incident on the panel.

Embodiment 18. A method for steering a signal, the method comprising: operating a panel in an environment, the panel including unit cells, a moveable metallic ground plane, and piezoelectric actuators configured to move the moveable metallic ground plane; determining a direction for steering a signal, wherein the signal is received from a base station, an access point, or a different panel; and changing a thickness of an air cavity formed in the panel under all the unit cells by causing the piezoelectric actuators to move the moveable metallic ground plane such that the signal is reflected in the determined direction.

Embodiment 19. The method of embodiment 18, wherein the piezoelectric actuators are caused to move the moveable metallic ground plane by applying a DC voltage to the piezoelectric actuators.

Embodiment 20. The method of embodiment 18 and/or 19, wherein the thickness of the air cavity under the unit cells is changed by controlling each of the piezoelectric actuators to provide equal displacement of the movable metallic ground plane.

Embodiment 21. A non-transitory storage medium having stored therein instructions that are executable by one or more hardware processors to perform operations comprising the operations of any one or more of embodiments disclosed herein.

The embodiments disclosed herein may include the use of a special purpose or general-purpose computer including various computer hardware or software modules, as discussed in greater detail below. A computer may include a processor and computer storage media carrying instructions that, when executed by the processor and/or caused to be executed by the processor, perform any one or more of the methods disclosed herein, or any part(s) of any method disclosed.

By way of example, and not limitation, such computer storage media may comprise hardware storage such as solid state disk/device (SSD), RAM, ROM, EEPROM, CD-ROM, flash memory, phase-change memory (“PCM”), or other optical disk storage, magnetic disk storage or other magnetic storage devices, or any other hardware storage devices which may be used to store program code in the form of computer-executable instructions or data structures, which may be accessed and executed by a general-purpose or special-purpose computer system to implement the disclosed functionality of the invention. Combinations of the above should also be included within the scope of computer storage media. Such media are also examples of non-transitory storage media, and non-transitory storage media also embraces cloud-based storage systems and structures, although the scope of the invention is not limited to these examples of non-transitory storage media.

Computer-executable instructions comprise, for example, instructions and data which, when executed, cause a general purpose computer, special purpose computer, or special purpose processing device to perform a certain function or group of functions. As such, some embodiments of the invention may be downloadable to one or more systems or devices, for example, from a website, mesh topology, or other source. As well, the scope of the invention embraces any hardware system or device that comprises an instance of an application that comprises the disclosed executable instructions.

As used herein, the term module, component, engine, agent, service, or the like may refer to software objects or routines that execute on the computing system. These may be implemented as objects or processes that execute on the computing system, for example, as separate threads. While the system and methods described herein may be implemented in software, implementations in hardware or a combination of software and hardware are also possible and contemplated. In the present disclosure, a ‘computing entity’ may be any computing system as previously defined herein, or any module or combination of modules running on a computing system.

In at least some instances, a hardware processor is provided that is operable to carry out executable instructions for performing a method or process, such as the methods and processes disclosed herein. The hardware processor may or may not comprise an element of other hardware, such as the computing devices and systems disclosed herein.

In terms of computing environments, embodiments of the invention may be performed in client-server environments, whether network or local environments, or in any other suitable environment. Suitable operating environments for at least some embodiments of the invention include cloud computing environments where one or more of a client, server, or other machine may reside and operate in a cloud environment.

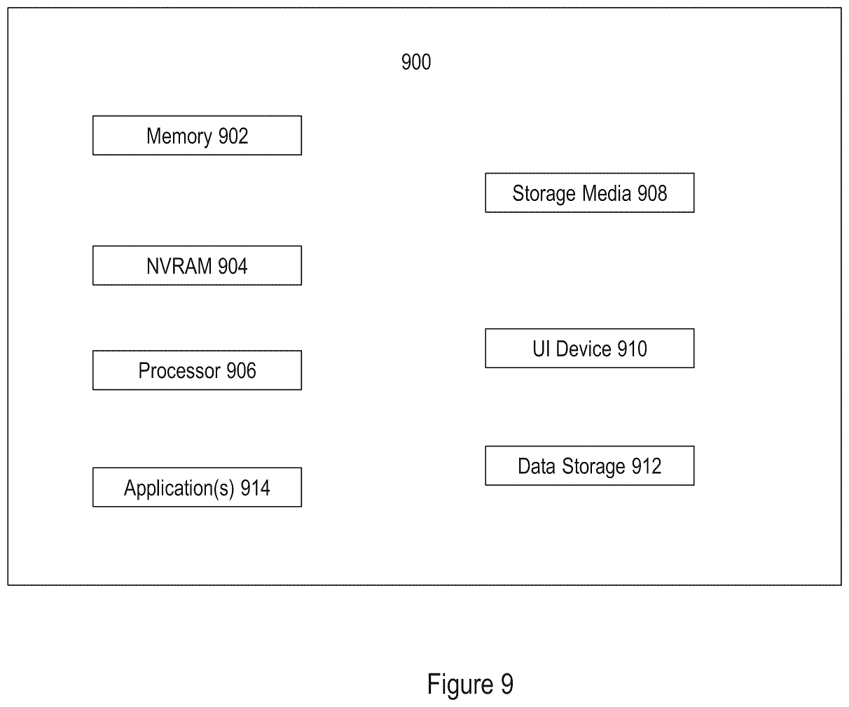

With reference briefly now to FIG. 9, any one or more of the entities disclosed, or implied, by the Figures and/or elsewhere herein, may take the form of, or include, or be implemented on, or hosted by, a physical computing device, one example of which is denoted at 900. As well, where any of the aforementioned elements comprise or consist of a virtual machine (VM), that VM may constitute a virtualization of any combination of the physical components disclosed in FIG. 9.

In the example of FIG. 9, the physical computing device 900 includes a memory 902 which may include one, some, or all, of random access memory (RAM), non-volatile memory (NVM) 904 such as NVRAM for example, read-only memory (ROM), and persistent memory, one or more hardware processors 906, non-transitory storage media 908, UI device 910, and data storage 912. One or more of the memory components 902 of the physical computing device 900 may take the form of solid state device (SSD) storage. As well, one or more applications 914 may be provided that comprise instructions executable by one or more hardware processors 906 to perform any of the operations, or portions thereof, disclosed herein.

Such executable instructions may take various forms including, for example, instructions executable to perform any method or portion thereof disclosed herein, and/or executable by/at any of a storage site, whether on-premises at an enterprise, or a cloud computing site, client, datacenter, data protection site including a cloud storage site, or backup server, to perform any of the functions disclosed herein. As well, such instructions may be executable to perform any of the other operations and methods, and any portions thereof, disclosed herein.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A panel comprising:
a substrate;
one or more metallic elements formed on a first surface of the substrate;
a moveable metallic ground plane separated from a second surface of the substrate by an air cavity positioned between the moveable metallic ground plane and the second surface of the substrate; and
a plurality of piezoelectric actuators attached to the moveable metallic ground plane and configured to increase or decrease a thickness of the air cavity by raising or lowering the moveable metallic ground plane,
wherein increasing or decreasing the thickness of the air cavity causes the panel to steer an electromagnetic beam that is directed toward the panel.

2. The panel of claim 1, further comprising:
a housing that comprises at least a bottom surface and two side surfaces;
the two side surfaces including first anchor portions that are configured to anchor the substrate to the housing;
the plurality of piezoelectric actuators and the moveable metallic ground plane being positioned between the substrate and the bottom surface of the housing; and
the housing including second anchor portions that attach the moveable metallic ground plane to the plurality of piezoelectric actuators.

3. The panel of claim 2, wherein the housing comprises a plurality of perforations that are configured to allow air that is interior to the housing to escape through the perforations when the plurality of piezoelectric actuators move the moveable metallic ground plane.

4. The panel of claim 3, wherein the perforations are positioned on one or more of the bottom surface of housing, one or both of the side surfaces of the housing, or the substrate.

5. The panel of claim 2, wherein the housing further includes control terminals that extend from the bottom surface of the housing and that are configured to provide a DC voltage to the piezoelectric actuators.

6. The panel of claim 2, wherein the housing is made of a transparent RF plastic.

7. The panel of claim 2, wherein the plurality of piezoelectric actuators are positioned at corners of the housing.

8. The panel of claim 1, wherein the one or more metallic elements are arranged in a grid-like array.

9. The panel of claim 1, wherein the substrate comprises a dielectric material.

10. The panel of claim 1, wherein the one or more metallic elements formed on the first surface of the substrate have a shape that is resonant with an incident signal or electromagnetic wave incident on the panel.

11. A panel comprising:
a housing; and
a plurality of unit cells arranged in a grid pattern, the plurality of unit cells including:
a substrate;
a metallic layer that includes one or more metallic elements for each of the unit cells, the metallic layer formed on a first surface of the substrate;
a moveable metallic ground plane separated from a second surface of the substrate by an air cavity positioned between the moveable metallic ground plane and the second surface of the substrate; and
a plurality of piezoelectric actuators attached to the moveable metallic ground plane and configured to increase or decrease a thickness of the air cavity by raising or lowering the moveable metallic ground plane,
wherein increasing or decreasing the thickness of the air cavity causes the panel to steer an electromagnetic beam that is directed toward the panel.

12. The panel of claim 11, wherein the housing comprises a plurality of perforations that are configured to allow air that is interior to the housing to escape through the perforations when the plurality of piezoelectric elements move the moveable metallic ground plane.

13. The panel of claim 11, wherein the plurality of piezoelectric actuators are positioned at corners of the housing.

14. The panel of claim 11, wherein the substrate comprises a dielectric material.

15. The panel of claim 11, wherein the housing further includes control terminals that extend from a bottom surface of the housing and that are configured to provide a DC voltage to the plurality of piezoelectric actuators.

16. The panel of claim 11, wherein the housing comprises at least a bottom surface and two side surfaces;
the two side surfaces including first anchor portions that are configured to anchor the substrate to the housing;
the plurality of piezoelectric actuators and the moveable metallic ground plane being positioned between the substrate and the bottom surface of the housing; and
the housing including second anchor portions that attach the moveable metallic ground plane to the plurality of piezoelectric actuators.

17. The panel of claim 11, wherein the one or more metallic elements formed on the first surface of the substrate have a shape that is resonant with an incident signal or electromagnetic wave incident on the panel.

18. A method for steering a signal, the method comprising:
operating a panel in an environment, the panel including unit cells, a moveable metallic ground plane, and piezoelectric actuators configured to move the moveable metallic ground plane;
determining a direction for steering a signal, wherein the signal is received from a base station, an access point, or a different panel; and
changing a thickness of an air cavity formed in the panel under all the unit cells by causing the piezoelectric actuators to move the moveable metallic ground plane such that the signal is reflected in the determined direction.

19. The method of claim 18, wherein the piezoelectric actuators are caused to move the moveable metallic ground plane by applying a DC voltage to the piezoelectric actuators.

20. The method of claim 18, wherein the thickness of the air cavity under the unit cells is changed by controlling each of the piezoelectric actuators to provide equal displacement of the moveable metallic ground plane.
